(19) United States
(12) Patent Application Publication
(10) Pub. No.: US 2010/0253395 A1
(43) Pub. Date: Oct. 7, 2010

(54) TRANSISTOR Gate Driver for Short Circuit Protection

(76) Inventors: Radu Pitigoi-Aron, San Jose, CA (US); Wanfeng Zhang, Palo Alto, CA (US)

Correspondence Address: Fountainhead Law Group, P.C.;Chad R. Walsh, 900 Lafayette Street, Suite 301, Santa Clara, CA, 95050, US

(21) Appl. No.: 12/752,992

(22) Filed: Apr. 1, 2010

Related U.S. Application Data
(60) Provisional application No. 61/167,479, filed on Apr. 7, 2009.

(51) Int. Cl. H03B 1/00

(52) U.S. Cl. 327/109

(57) ABSTRACT

Particular embodiments generally relate to driver structures. In one embodiment, an apparatus includes a first driver that drives a first current for a transistor. The first driver drives the first current during a first portion of a drive time of driving the transistor. The first driver is OFF during a second portion. A second driver drives a second current for the transistor during the second portion.

### CROSS REFERENCE TO RELATED APPLICATIONS

The present application claims priority to U.S. Provisional App. No. 61/167,479 for “MOSFET Driver Method and Circuit” filed Apr. 7, 2009, the contents of which is incorporated herein by reference in their entirety.

### BACKGROUND

Particular embodiments generally relate to short circuit protection.

Unless otherwise indicated herein, the approaches described in this section are not prior art to the claims in this application and are not admitted to be prior art by inclusion in this section.

Many applications may use metal oxide semiconductor field effect transistors (MOSFETs) in switching configurations where the transistors are driven either on or off with a very short time in between the on state and the off state. The MOSFETs are essentially charge controlled devices where an equivalent capacitor between the gate and source can be approximated for the MOSFET input. The equivalent capacitor may be referred to as a gate capacitor, or Cgs.

In one conventional example, the MOSFET is turned on when the capacitor is fully charged. That is, a current can flow between the drain and source of the MOSFET. The MOSFET is turned off when the capacitor is empty and thus no current flows between the drain and source. The transient time to switch the MOSFET between the on and off states is determined by a speed at which necessary electric charge is loaded or unloaded into the gate capacitor. To load or unload the necessary electric charge, MOSFET gate drivers need to use charge and discharge currents that are very large. This causes the MOSFET to change state very fast. Implementations of MOSFET gate drivers use structures that are capable of supplying large peak currents. Because the MOSFET gate drivers have to drive essentially a capacitor, the MOSFET gate drivers are not designed to support the large currents for long periods of time. This saves area in the silicon's die.

In some applications, the MOSFET gate driver's outputs are short-circuited to ground. This causes stressful conditions and could damage the driver, which is not designed to support the large currents short circuited to ground. Accordingly, different short circuit protection schemes are used to protect the driver. However, the schemes are complex and increase the die size of the driver chip. Also, the schemes may not always cover all the conditions that may arise.

FIG. 1 depicts a conventional system 100 for short circuit protection. A driver 102 drives MOSFET 104 with a large current during a drive time. The drive time is the time when the gate capacitor Cgs is charged and consequently MOSFET 104 is conducting. The stop time is when the gate capacitor Cgs is discharged and MOSFET 104 is not conducting. During drive time of system 100, a current limiter 106 may pull the gate of MOSFET 104 to ground to discharge capacitor Cgs. For example, current limiter 106 may be part of a power factor correction circuit. In one example, power factor correction is being performed for a load, such as a switch mode power supply 208. Driver 102 may be damaged if the large current is short-circuited to ground. Additionally, a large amount of power is dissipated by driver 102 when the gate is short-circuited to ground, which may also damage driver 102.

A short circuit protection block 110 is included in system 100 to protect driver 102 when a short circuit occurs. Short circuit protection block 110 senses a current across a resistor 112. If the current exceeds a threshold, a control signal is sent to driver 102 to shut driver 102 off. The use of thresholds requires complex logic, which increases the area used in the chip. Other more complicated schemes may be used that also increase the area used.

### SUMMARY

Particular embodiments generally relate to driver structures. In one embodiment, an apparatus includes a first driver that drives a first current for a transistor. The first driver drives the first current during a first portion of a drive time of driving the transistor. The first driver is OFF during a second portion. A second driver drives a second current for the transistor during the second portion.

In one embodiment, an apparatus is provided comprising: a first driver driving a first current for a transistor, wherein the first driver is ON for a first portion of a drive time to drive the transistor and the first driver is OFF for a second portion of the drive time; and a second driver driving a second current for the transistor, wherein the second driver is driving the second current during the second portion of the drive time to drive the transistor.

In another embodiment, a method is provided comprising: driving a first current to a transistor for a first portion of a drive time to drive the transistor; not driving the first current for a second portion of the drive time; and driving a second current for the transistor during the second portion of the drive time.

The following detailed description and accompanying drawings provide a better understanding of the nature and advantages of the present invention.

### BRIEF DESCRIPTION OF THE DRAWINGS

FIG. 1 depicts a conventional system for short circuit protection.

FIG. 2 depicts a system for providing short circuit protection according to one embodiment.

FIG. 3 depicts a graph of a timing diagram according to one embodiment.

FIG. 4 shows an example of applying switching logic to a sustaining driver and a full driver according to one embodiment.

FIG. 5 depicts an example showing the sustaining driver and the full driver according to one embodiment.

### DETAILED DESCRIPTION

Described herein are techniques for short circuit protection. In the following description, for purposes of explanation, numerous examples and specific details are set forth in order to provide a thorough understanding of embodiments of the present invention. Particular embodiments as defined by the claims may include some or all of the features in these examples alone or in combination with other features described below, and may further include modifications and equivalents of the features and concepts described herein.

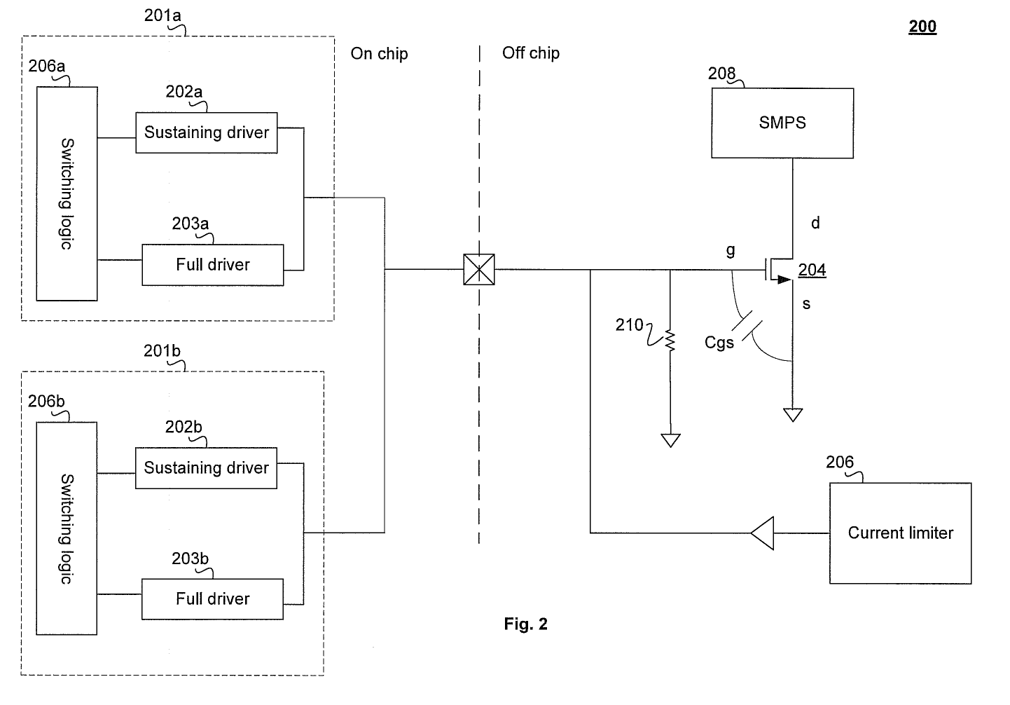

FIG. 2 depicts a system 200 for providing short circuit protection according to one embodiment. In system 200, a chip includes a first driver circuit 201a including sustaining driver 202a, a full driver 203a, and switching logic 206a and a second driver circuit 201b including sustaining driver 202b, a full driver 203b, and switching logic 206b. A MOSFET 204, a current limiter 206, a switch mode power supply (SMPS) 208, and a resistor 210 may be included off the chip.

First driver circuit 201a and second driver circuit 201b may be implemented in separate circuits in chip 200. First driver circuit 201a may drive current in a first direction, such as supply current to MOSFET 204. Second driver circuit 201b may drive current in a second direction, such as drawing current.

To drive MOSFET 204 on and off, a large current is needed to charge or discharge the gate capacitor Cgs across MOSFET 204 in a required transient time. The required transient time may be a time that is desired to switch MOSFET 204 between on and off states. In one embodiment, full driver 203a provides a necessary full current to charge and full driver 203b provides a necessary full current to discharge the gate capacitor for achieving the required transient time to drive MOSFET 204 between ON and OFF states. Sustaining drivers 202a and 202b supply a smaller sustaining current than full drivers 203a and 203b. The smaller current is sufficient to sustain the charge of the gate capacitor in a charged state once full driver 203a charges the gate capacitor. Also, sustaining driver 203b keeps a low impedance across the gate capacitor Cgs thereby keeping the gate capacitor in a discharged state.

In some cases, the gate of MOSFET 204 may be pulled to ground. For example, current limiter 206 may be part of a power factor correction circuit. In one example, power factor correction is being performed for switch mode power supply 208. Although switch mode power supply 208 is described, other loads may be used. For example, any powered coil may be used for the load.

Power factor correction shapes an input current to be in phase and sinusoidal with an input voltage. In power factor correction, the current through MOSFET 204 is monitored and if it exceeds a threshold, the current may be cut off. In this case, the gate of MOSFET 204 is pulled to ground by current limiter 206. Although power factor correction and current limiting is described, other events may be the cause of the gate of MOSFET 204 being pulled to ground.

Particular embodiments provide short circuit protection by not having full driver 203a be ON for an entire drive time for MOSFET 204 The drive time is when MOSFET 204 is turned on, conducts current from the drain to source, and then is turned off. Full driver 203a supplies current to fully charge the gate capacitor. Once the gate capacitor is charged, the full current required to turn MOSFET 204 on in the required transient time is not needed to sustain the charge of the gate capacitor. Thus, the full current from full driver 203a is not needed. The sustaining current provided by sustaining driver 202a can be used to sustain the charge of the gate capacitor until MOSFET 204 needs to be turned OFF. Accordingly, particular embodiments turn full driver 203a off during a portion of the drive time.

When it is time to discharge the gate capacitor, full driver 203b may be turned on to draw current to discharge the gate capacitor, which turns MOSFET 204 off. Once MOSFET 204 is off, sustaining driver 202b is used to draw a sustaining current.

Particular embodiments according to this disclosure provide natural short circuit protection by recognizing that the full current is not needed to drive the gate capacitor once it is charged. Because full driver 203a is not needed to sustain the charge, full driver 203a is turned OFF during at least a portion of this time. If a short circuit occurs when full driver 203a is OFF, sustaining driver 202a is configured to withstand the short circuit condition without damaging the chip. Also, the power dissipated by the short circuit is significantly less than if full driver 203a was ON. For example, if sustaining driver 202a is supplying a very small sustaining current, then the power dissipated is much lower than if the larger full current of full driver 203a is being supplied.

The above is also true for discharging the gate capacitor. The full current does not need to be drawn once the gate capacitor is discharged. Full driver 203b is turned OFF after this time. If a short circuit occurs when full driver 203b is OFF, sustaining driver 202b is configured to withstand the short circuit condition without damaging the chip.

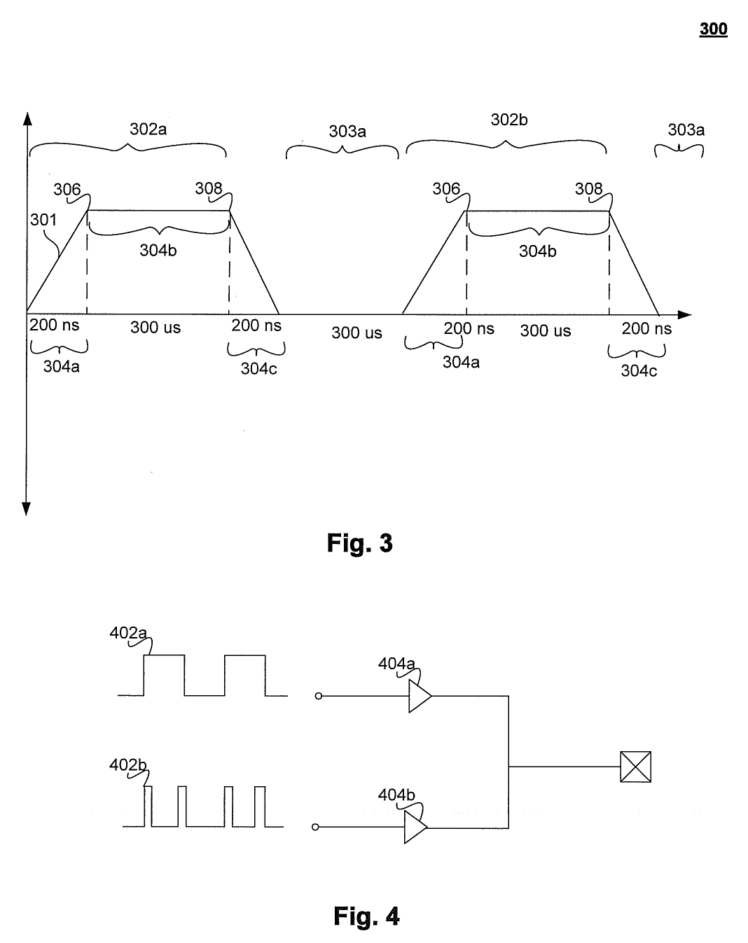

FIG. 3 depicts a graph 300 of a timing diagram according to one embodiment. A waveform 301 shows drive times 302a and 302b for charging the gate capacitor. First driver circuit 201a is used to supply current. For a first portion 304a of drive times 302a and 302b, the gate capacitor is being charged by full driver 203a. Also, sustaining driver 202a may also be supplying current. At a point 306, the gate capacitor is fully charged. For first portion 304a, the full current of full driver 203a is needed to charge the gate capacitor in the required transient time to turn MOSFET 2-204ON. In this case, both sustaining driver 202a and full driver 203a may be ON. However, at point 306, the full current of full driver 203a is no longer needed. Thus, full driver 203a may be turned OFF around this time.

For a second portion 304b, only sustaining driver 202a is on. During this time, only a small current is being supplied. The current to sustain the charge is based on resistor 210, which may be a large value, such as 100 kOhm-1 Mohm. The sustaining current may thus be low to sustain the charge. If a short circuit condition occurs, only a small amount of power will be dissipated due to the small amount of sustaining current being supplied.

At a point 308, the gate capacitor is discharged for a required transient time. Driver circuit 201b may be used to draw current to discharge the capacitor Cgs. The full current of full driver 203a is needed to switch MOSFET 2-204 off in the required transient time during a third portion 304c. Full driver 203b is turned on around this point and draws the full current to discharge the gate capacitor. In one embodiment, full driver 203b and sustaining driver 202b are both on during third portion 304c of the drive time to discharge the gate capacitor. Also, only full driver 203b is on during third portion 304c. Once the gate capacitor has been discharged, full driver 203b may then be off during a fourth portion 303a.

Because full drivers 203a and 203b are off for a portion of the drive time, the time in which a short circuit may damage system 200 is reduced. For example, if a short circuit occurs during portions 304a or 304c, there is a slight chance that system 200 may be damaged. However, portions 304a and 304c are short periods of time compared to second portion 304b and fourth portion 303a. For example, second portion 304b and fourth portion 303a may both be 3 microseconds as compared to 200 nanoseconds for portions 304a and 304c. Thus, for a majority of the drive time, sustaining drivers 202a and 202b is only on. Sustaining drivers 202a and 202b are designed such that they are able to sustain a short circuit condition without any damage or significant power dissipation increase for system 200 to limit damage from a short circuit.

A margin of time greater than the time required to turn MOSFET 204 on and off may be used to determine when to turn full drivers 203a and 203b OFF and ON. For example, full driver 203a may be switched OFF after point 306 and full driver 203b switched on before point 308. This allows for some variance in the time taken to turn MOSFET 204 ON and OFF. For example, portions 304a and 304c may be 200 nanoseconds. The times that full driver 203a is on for first portion 304a and full driver 203b is on third portion 304c may be set at 400 nanoseconds. This allows a 200 nanosecond margin for turning MOSFET 204 on and off.

Referring back to FIG. 2, switching logic 206a or 206b is used to turn ON and OFF sustaining driver 202a and full driver 203a or sustaining driver 202b and full driver 203b. For example, sustaining driver 202a may be turned ON for the entire drive time. However, full driver 203a is turned ON for first portion 304a, but not second portion 304b. Although sustaining driver 202a is described as being ON during the full drive time, sustaining driver 202a may be turned OFF during first portion 304a

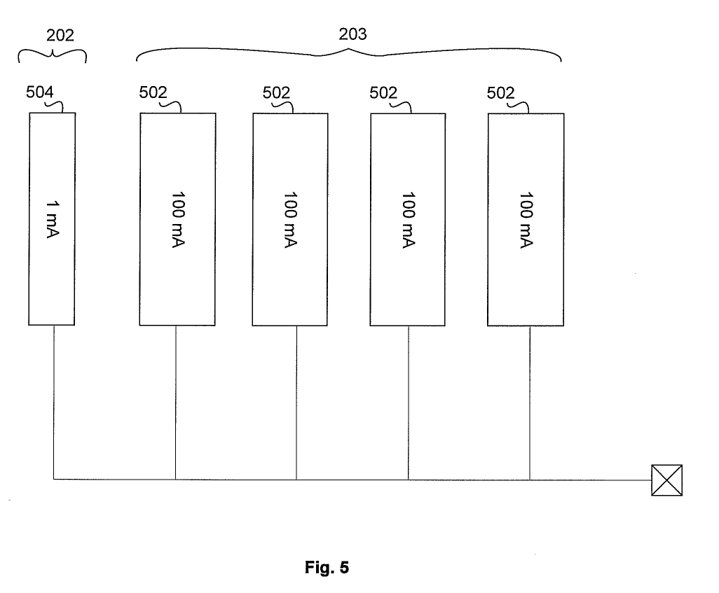

Switching logic 206 may be used to generate signals that turn ON and OFF sustaining driver 202 and full driver 203 in different periods. This concept may be applied to both first driver circuit 101a and second driver circuit 101b. Full driver 200 may reference either full driver 203a or 203b and sustaining driver 202 may reference either sustaining driver 202a or 202b in the following description. FIG. 4 shows an example of applying switching logic 206 to sustaining driver 202 and full driver 203 according to one embodiment. As shown, a first signal 402a is sent to an amplifier 404a for sustaining driver 202. Also, a second signal 402b is input through an amplifier 404b for full driver 203. Signal 402a is ON for 3.4 microseconds, OFF for 3.4 microseconds, and ON for 3.4 microseconds. However, signal 402b is ON for 400 nanoseconds, OFF for 2.6 microseconds, and ON for 400 microseconds. After being OFF for 3.4 microseconds, signal 402b is again ON for 400 nanoseconds, OFF for 2.6 microseconds, and ON for 400 nanoseconds.

Signal 402a drives amplifier 404a for the full drive time for sustaining driver 202. Also, signal 402b drives amplifier 404b for a portion of the full drive time for full driver 3-302.

Switching logic 206 may generate signals 402a and 402b. A person of skill in the art will appreciate how to generate signals 402a and 402b in accordance with the teachings and disclosure herein. In one example, a series of flip-flops may be used to generate the pulses of signals 402a and 402b.

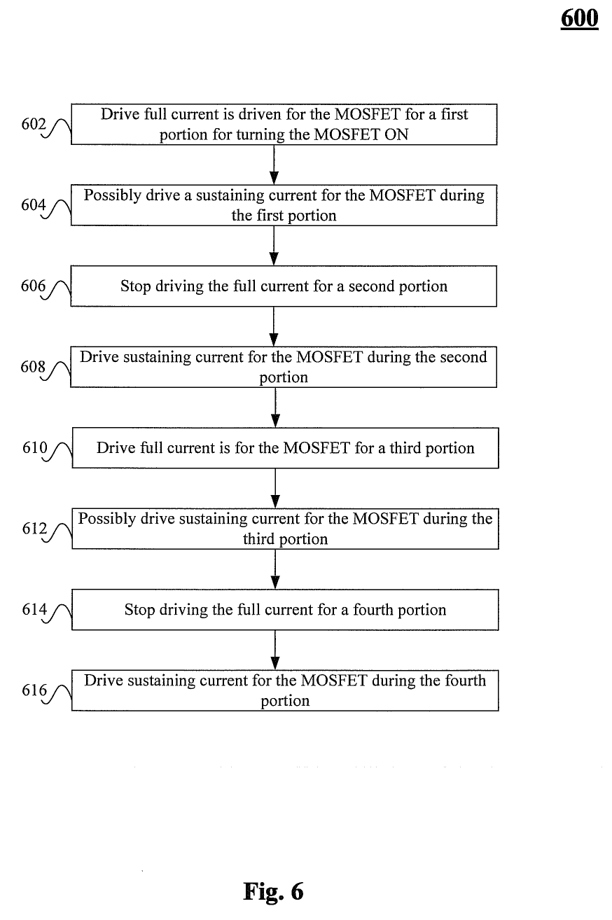

In one embodiment, full driver 203 may be implemented using multiple current sources. For example, multiple MOSFETs may be used. FIG. 5 depicts an example showing sustaining driver 202 and full driver 203 according to one embodiment. This concept may be applied to both first driver circuit 101a and second driver circuit 101b. In one embodiment, sustaining driver 202 and full driver 203 are made in different structures of a chip.

Full driver 203 may include multiple current sources. For example, each finger 502 may be a MOSFET that is configured to supply or draw a certain amount of current. In one example, each finger 502 may supply 100 milliamps. If 10 fingers are provided, then 1 amp of current may be supplied by full driver 203.

Sustaining driver 202 may be a single finger 504 that supplies or draws the sustaining current. For example, finger 504 may supply a 1 milliamp current. Although a single finger is described, any number of fingers 504 may be used for sustaining driver However, the amount of current supplied by fingers 504 of sustaining driver 202 is less than the amount of current supplied by fingers 502 of full driver 203.

Switching logic 206 is applied to fingers 502 and 504 such that they are switched ON and OFF as described above. Accordingly, if a short circuit occurs with only finger 504 ON, the power dissipated with a 1 milliamp is a lot less than the power dissipated if 1 amp of current is ON during the short circuit.

FIG. 6 depicts a simplified flow chart 600 of a method for short circuit protection according to one embodiment.

At 602, a full current is driven for MOSFET 204 for a first portion for turning MOSFET 204 ON. For example, the full current may be supplied. The full current is sufficient to turn MOSFET 204 ON.

At 604, a sustaining current may or may not be driven to MOSFET 204 during the first portion. For example, the sustaining current may be supplied. In one embodiment, the sustaining current is driven during the first portion of turning the MOSFET ON. In another embodiment, the sustaining current may not be on during the first portion.

At 606, after the first portion is over, the full current is not driven for a second portion of the full drive time. At 608, the sustaining current is driven for MOSFET 204 during the second portion. For example, the sustaining current may be supplied. The sustaining current is sufficient to keep the gate capacitor charged during the second portion while MOSFET 204 is ON.

At 610, after the second portion is over, the full current is driven to MOSFET 204 for a third portion. For example, the full current may be drawn. The full current is sufficient to turn MOSFET 2-204 OFF.

At 612, the sustaining current may or may not be driven to MOSFET 204 during the third portion. For example, the sustaining current may be drawn. In one embodiment, the sustaining current is driven during the third portion of turning the MOSFET OFF. In another embodiment, sustaining current may not be on during the third portion.

At 614, after the third portion is over, the full current is not supplied or drawn for a fourth portion. At 616, the sustaining current is driven for MOSFET 204 during a fifth portion. For example, the sustaining current may be supplied. The sustaining current is sufficient to keep the gate capacitor discharged during the fifth portion while MOSFET 204 is OFF.

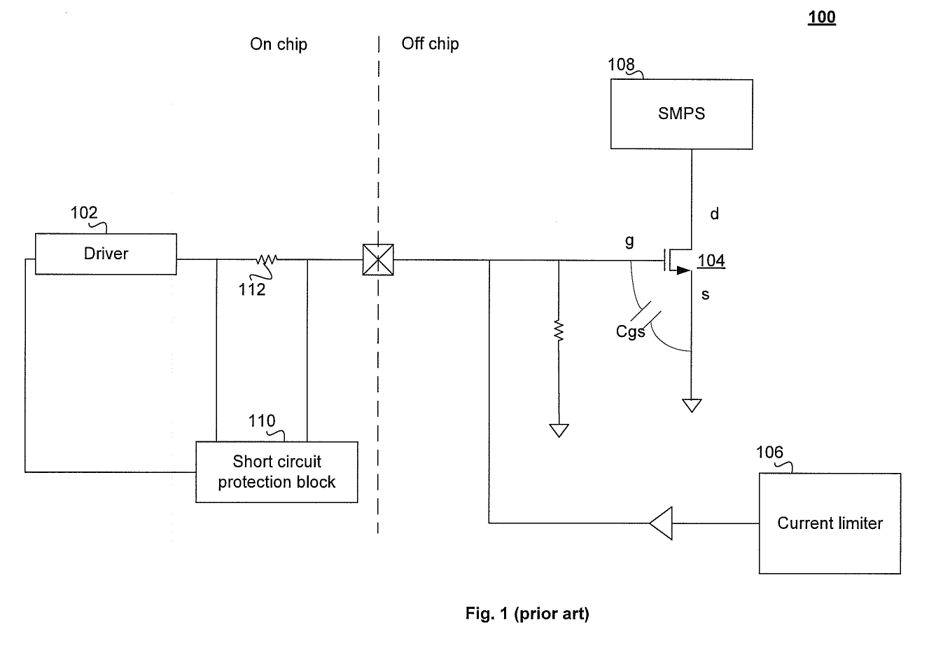

Switching logic 206 can be implemented in an area-efficient design that does not require as complex of logic as short circuit protection block 110 of FIG. 1. By switching full driver 203a OFF when it is not needed during second portion 304b, natural short circuit protection for the chip is provided. The same is true for full driver 203b. Short circuit protection is thus inherent in the design. Thresholds are not needed to determine if a short circuit condition is occurring, which is less complex, saves area on the silicon's die, and also decreases cost.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

The above description illustrates various embodiments of the present invention along with examples of how aspects of the present invention may be implemented. The above examples and embodiments should not be deemed to be the only embodiments, and are presented to illustrate the flexibility and advantages of the present invention as defined by the following claims. Based on the above disclosure and the following claims, other arrangements, embodiments, implementations and equivalents may be employed without departing from the scope of the invention as defined by the claims.

What is claimed is:

1. An apparatus comprising:
a first driver driving a first current for a transistor, wherein the first driver is ON for a first portion of a drive time to drive the transistor and the first driver is OFF for a second portion of the drive time; and
a second driver driving a second current for the transistor, wherein the second driver is driving the second current during the second portion of the drive time to drive the transistor.

2. The apparatus of claim 1, wherein the first current is able to charge or discharge a gate capacitor of the transistor.

3. The apparatus of claim 2, wherein the second current is able to sustain a charged state of the gate capacitor or sustain a discharged state of the gate capacitor.

4. The apparatus of claim 3, wherein the first current is able to charge or discharge the gate capacitor in a required transient time period to switch the transistor between ON and OFF states.

5. The apparatus of claim 1, further comprising switching logic configured to switch the first driver ON for the first portion of drive time and switch the second driver ON for the second portion of the drive time,
wherein the switching logic switches the first driver OFF during the second portion of the drive time.

6. The apparatus of claim 1, wherein a first pulse signal is used to switch the first driver ON and OFF, and a second pulse signal is used to switch the second driver ON and OFF,
wherein the first pulse signal is high for the first portion of the drive time and the second pulse signal is high for the second portion of the drive time.

7. The apparatus of claim 1, wherein the second driver is configured to sustain a short circuit condition.

8. The apparatus of claim 1, wherein the second current is smaller than the first current.

9. The apparatus of claim 1, wherein the second driver comprises less current sources than the first driver.

10. The apparatus of claim 1, wherein the second driver is ON during the first portion and the second portion.

11. The apparatus of claim 1, wherein power dissipated when a short circuit occurs is less when the second current is being supplied without the first current being supplied than if the first current is being supplied when the short circuit occurs.

12. The apparatus of claim 1, wherein:
the first driver supplies the first current to the transistor during the first portion of the drive time to drive the transistor ON, and
the second driver supplies the second current to the transistor during the second portion of the drive time to sustain the transistor,
the apparatus further comprising:
a third driver drawing a third current from the transistor, wherein the third driver is ON for a third portion of the drive time to drive the transistor OFF and the third driver is OFF for a fourth portion of the drive time; and
a fourth driver driving a fourth current to the transistor, wherein the fourth driver is drawing the fourth current during the fourth portion of the drive time.

13. The apparatus of claim 1, wherein the transistor comprises a metal oxide semiconductor field effect transistors (MOSFET).

14. A method comprising:
driving a first current for a transistor for a first portion of a drive time to drive the transistor;
not driving the first current for a second portion of the drive time; and
driving a second current for the transistor during the second portion of the drive time.

15. The method of claim 14, wherein the first current is able to charge or discharge a gate capacitor of the transistor.

16. The method of claim 15, wherein the second current is able to sustain a charged state of the gate capacitor or sustain a discharged state of the gate capacitor.

17. The method of claim 15, wherein the first current is able to charge or discharge the gate capacitor in a required transient time period to switch the transistor between ON and OFF states.

18. The method of claim 14, further comprising:
driving a third current to the transistor for a third portion of the drive time to drive the transistor;
not driving the third current for a fourth portion of the drive time; and
driving a fourth current for the transistor during the fourth drive time.

19. The method of claim 14, further comprising:
generating a first pulse signal used to turn a first driver ON and OFF, the first driver driving the first current; and
generating a second pulse signal is used to turn the second driver ON and OFF, the second driver driving the second current,
wherein the first pulse signal is high for the first portion of the drive time and the second pulse signal is high for the second portion of the drive time.

20. The method of claim 14, wherein the second current is configured to sustain a short circuit condition without damaging a structure supplying the first current and the second current.
